(19) United States
(12) Patent Application Publication
(10) Pub. No.: US 2026/0214961 A1
(43) Pub. Date: Jul. 23, 2026

(54) HIGH PERFORMANCE SCHOTTKY BARRIER DIODE STRUCTURE

(71) Applicant: Microchip Technology Incorporated, Chandler, AZ (US)

(72) Inventors: Yogesh Kumar Sharma, Colorado Springs, CO (US); Shesh Mani Pandey, Gilbert, AZ (US)

(73) Assignee: Microchip Technology Incorporated, Chandler, AZ (US)

(21) Appl. No.: 19/455,466

(22) Filed: Jan. 21, 2026

Related U.S. Application Data
(60) Provisional application No. 63/748,793, filed on Jan. 23, 2025.

(51) Int. Cl. H10D 64/64; H10D 8/01; H10D 8/60; H10D 64/01

(52) U.S. Cl. CPC H10D 64/64; H10D 8/051; H10D 8/60; H10D 64/0121

(57) ABSTRACT

A Schottky barrier diode (SBD) comprises a volume of semiconductor material presenting opposite first and second ends, a plurality of laterally spaced pockets of doped material extending into the volume of semiconductor material adjacent the first end, a Schottky layer located adjacent the first end between the pockets of doped material of doped material, and a silicide layer located adjacent each pocket of doped material. The Schottky and silicide layers include dissimilar metals

### CROSS-REFERENCE TO RELATED APPLICATIONS

The current patent application claims the benefit of and priority from U.S. Provisional Application Ser. No. 63/748,793 titled “HIGH PERFORMANCE SCHOTTKY BARRIER DIODE” and filed January 23, 2025, and U.S Provisional Application Ser. No. 63/756,636 titled "HIGH PERFORMANCE SCHOTTKY BARRIER DIODE STRUCTURE and filed February 10, 2025. The Provisional Applications are hereby incorporated by reference, in their entirety, into the current patent application as if fully set forth herein.

### TECHNICAL FIELD

The present disclosure relates to Schottky barrier diodes.

### BACKGROUND

A Schottky barrier diode (SBD) is a semiconductor diode formed by the junction of a semiconductor with a metal. The relatively low forward voltage of SBDs is desirable for applications requiring fast switching, such as power systems, radio frequency (RF) systems, and logic circuits. It is generally desirable to improve the performance and reduce the cost of SBDs, but it can be difficult to do so.

This background discussion is intended to provide related information, and is not necessarily prior art.

### SUMMARY OF THE INVENTION

In various examples of the present disclosure, a Schottky barrier diode (SBD) includes a volume of semiconductor material presenting opposite first and second ends, a plurality of laterally spaced pockets of doped material extending into the volume of semiconductor material adjacent the first end, a Schottky layer located adjacent the first end between the pockets of doped material, and a silicide layer located adjacent each pocket of doped material. The Schottky and silicide layers include dissimilar metals.

In various examples of the present disclosure, a method of making an SBD includes: growing a volume of semiconductor material to present a first end and a second end opposite the first end; implanting a plurality of laterally spaced pockets of doped material adjacent the first end; providing a Schottky layer at the first end and of the volume of semiconductor material adjacent the first end between the pockets of doped material; and providing a silicide layer adjacent each pocket of doped material. The Schottky and silicide layers include dissimilar metals.

### BRIEF DESCRIPTION OF THE DRAWINGS

FIG. 1 is a cross-sectional elevation view of an example SBD having a Schottky layer including first and second metal layers;

FIG. 2 is a cross-sectional elevation view of an example SBD having a Schottky layer including a single metal layer;

FIG. 3 is a cross-sectional elevation view of an example SBD including a silicon layer underlying a Schottky layer;

FIG. 4 illustrates an example method for making an SBD;

FIG. 5A is a cross-sectional elevation view of an example SBD during an initial manufacturing stage;

FIG. 5B is a cross-sectional elevation view of an example SBD following formation of doped material pockets;

FIG. 5C is a cross-sectional elevation view of an example SBD following formation of a first metal layer;

FIG. 5D is a cross-sectional elevation view of an example SBD following formation of a second metal layer;

FIG. 5E is a cross-sectional elevation view of an example SBD following formation of a silicide layer; and

FIG. 5F is a cross-sectional elevation view of an example SBD following contact placement.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower, vertical, horizontal (or lateral)) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Examples provide a Schottky barrier diode (SBD). The example SBD may be suitable for high-voltage applications and may operate at a voltage greater than one thousand (1,000) volts (V). More specifically, the example SBD may be rated for a voltage of around twelve hundred (1,200) V. It will be appreciated by one of ordinary skill in the art that the example SBD may, according to certain aspects, be suitable for lower voltage applications without departing from the scope of the present disclosure. The example SBD may be implemented as a stand-alone device, or may be integrated with other devices (e.g., other diodes, transistors, and the like) as part of a semiconductor package.

The example SBD may include a Schottky layer, a silicide layer, and a volume of semiconductor material. The Schottky layer and the silicide layer may extend across a top end of the volume of semiconductor material. The Schottky layer and the silicide layer may include dissimilar metals. The Schottky layer may include tungsten. The silicide layer may include titanium silicide. The tungsten layer may reduce a forward voltage of the SBD, thereby reducing the switching time and increasing the current carrying capacity of the example SBD. The silicide layer may reduce leakage of the example SBD.

Further, the example SBD may include a silicon layer implanted along the top end of the volume of semiconductor material. The volume of semiconductor material may include silicon carbide (SiC). Silicon has a bandgap of about 1.12 electron Volts (eV). SiC has a bandgap of about 3.26 eV. Accordingly, the silicon layer may further reduce the forward voltage of the SBD due to the bandgap of silicon being lower than the bandgap of SiC.

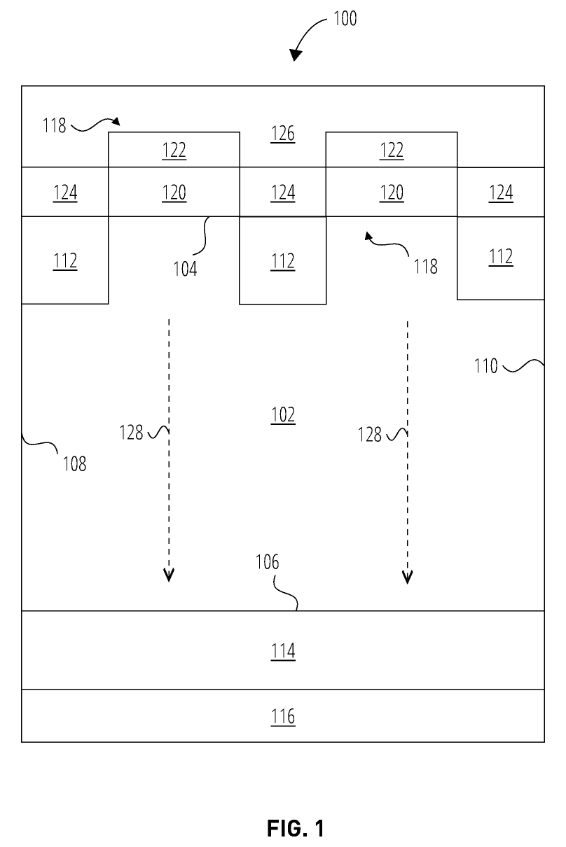

Referring to FIG. 1, an example of an SBD 100 is shown. The SBD 100 may generally include a volume of semiconductor material 102, laterally spaced pockets of doped material 112, a Schottky layer 118, and a silicide layer 124. The Schottky layer 118 and the silicide layer 124 may include dissimilar metals.

The volume of semiconductor material 102 may present a first end 104, a second end 106 opposite and vertically spaced from the first end 104, a first side 108, and a second side 110 opposite and laterally spaced from the first side 108. The volume of semiconductor material 102 may be constructed from or include an N-type epitaxial semiconductor material, such as silicon carbide (SiC). However, it is within the ambit of the present disclosure that the volume of semiconductor material 102 may be constructed from silicon.

The pockets of doped material 112 may be constructed from or otherwise include a P+ material. The pockets of doped material 112 may be laterally spaced between the first side 108 and the second side 110. The pockets of doped material 112 may be implanted, deposited, or otherwise provided adjacent the first end 104. The pockets of doped material 112 may extend from the first end 104 toward the second end 106. The pockets of doped material 112 may be identical in shape and configuration and spaced equidistantly, although certain SBD examples contemplate variously shaped pockets, unequal spacing between the pockets, etc.

A cathode substrate 114 is located at the second end 106 of the volume of semiconductor material 102 and may be constructed from or include an N+ substrate material. The volume of semiconductor material 102 may be grown or otherwise formed on the cathode substrate 114. A cathode contact 116 may be located adjacent the cathode substrate 114 and spaced apart from the second end 106.

The Schottky layer 118 may form a Schottky contact with the volume of semiconductor material 102. The Schottky layer 118 may include a first metal layer 120 and a second metal layer 122. The first metal layer 120 may contact the first end 104 of the volume of semiconductor material 102. The first metal layer 120 and the second metal layer 122 may be formed of dissimilar metals, although alternative examples contemplate forming the first and second metal layers of the same material. For example, the first metal layer 120 may include tungsten and the second metal layer 122 may include titanium. According to some aspects of the example SBD, it is within the ambit of the present disclosure that the first and/or second metal layers may include other metal or metal alloys including titanium, molybdenum, platinum, chromium, tungsten, aluminum, nickel, and the like, and combinations thereof.

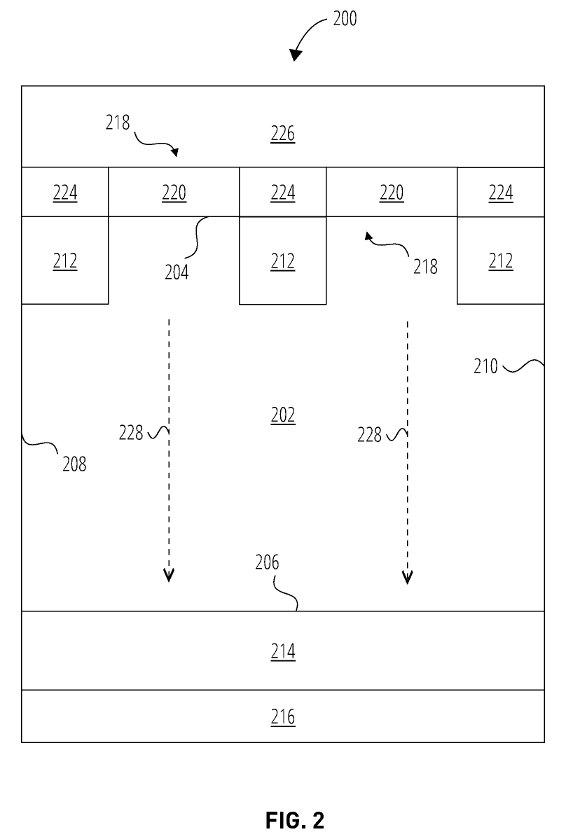

It is within the ambit of the present disclosure that the Schottky layer 118 may include only the first metal layer 120, as described below with respect to the example shown in FIG. 2.

The silicide layer 124 may be located adjacent each pocket of doped material 112. The silicide layer 124 may comprise titanium silicide, however it is within the ambit of the present disclosure that the silicide layer may include other or additional silicides, such as cobalt silicide or nickel silicide. The silicide layer 124 may form an Ohmic contact with the pockets of doped material 112. The Ohmic contact may reduce leakage of the SBD 100.

An anode contact 126 may be located adjacent the silicide layer 124 and the Schottky layer 118. The anode contact 126 may be spaced apart from the first end 104. The second metal layer 122 may be interposed between the first metal layer 120 and the anode contact 126, such that the second metal layer 122 may contact the anode contact 126. The anode contact 126 may include a conductive metal, such as aluminum, copper, nickel, or combinations thereof. In various examples, the anode contact 126, the first metal layer 120, and the second metal layer 122 may be formed of dissimilar metals although alternative examples contemplate forming the anode contact and at least the second metal layer of the same material.

Channels 128 may be provided by a channel portion of the volume of semiconductor material 102. The channels 128 may extend through the volume of semiconductor material 102 between the first end 104 and the cathode substrate 114. The majority charge carriers may move and the electrical current may flow through the channels 128. It will be understood by one of ordinary skill in the art that the dashed lines representing the channels 128 are merely representative and charge carriers moving through the channels 128 do not necessarily follow a single, straight line.

Referring to FIG. 2, an example of an SBD 200 is shown. The SBD 200 may generally include a volume of semiconductor material 202, laterally spaced pockets of doped material 212, a Schottky layer 218, and a silicide layer 224. The Schottky layer 218 and the silicide layer 224 may include dissimilar metals.

The volume of semiconductor material 202 may present a first end 204, a second end 206 opposite and vertically spaced from the first end 204, a first side 208, and a second side 210 opposite and laterally spaced from the first side 208.

A cathode substrate 214 is located at the second end 206 of the volume of semiconductor material 202 and may be constructed from or include an N+ substrate material. An anode contact 226 may be located above the Schottky layer 218 and spaced apart from the first end 204. Channels 228 may be provided by a channel portion of the volume of semiconductor material 202.

In various examples, the volume of semiconductor material 202, pockets of doped material 212, cathode substrate 214, cathode contact 216, and silicide layer 224 may be substantially identical to the analogous volume of semiconductor material 102, pockets of doped material 112, cathode substrate 114, cathode contact 116, and silicide layer 124 of FIG. 1 and are not described again here for the sake of brevity.

The Schottky layer 218 may form a Schottky contact with the volume of semiconductor material 202. The Schottky layer 218 may include a metal layer 220. The metal layer 220 may contact the first end 204 of the volume of semiconductor material 202 and the anode contact 226. The metal layer 220 may include tungsten. The metal layer 220 and the anode contact 226 may be formed of dissimilar metals although alternative examples contemplate forming the anode contact and Schottky metal of the same material. It is noted that, with the Schottky layer including only the single metal layer 220 (without a second layer upper layer 122 as included in the SBD 100 of FIG. 1), the anode contact 226 may be formed as a uniform layer of contact material (as illustrated).

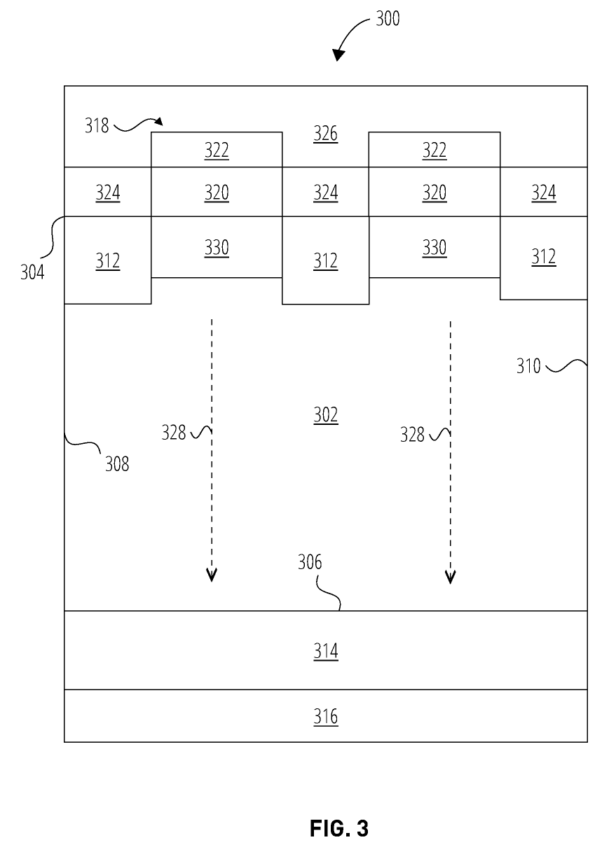

Referring to FIG. 3, another example of an SBD 300 is shown. The SBD 300 may generally include a volume of semiconductor material 302, laterally spaced pockets of doped material 312, a Schottky layer 318, a silicide layer 324, and a silicon layer 330. The Schottky layer 318 and the silicide layer 324 may include dissimilar metals.

The volume of semiconductor material 302 may present a first end 304, a second end 306 opposite and vertically spaced from the first end 304, a first side 308, and a second side 310 opposite and laterally spaced from the first side 308.

A cathode substrate 314 is located at the second end 306 of the volume of semiconductor material 302 and may be constructed from or include an N+ substrate material. An anode contact 326 may be located above the Schottky layer 318 and spaced apart from the first end 304. Channels 328 may be provided by a channel portion of the volume of semiconductor material 302.

The Schottky layer 318 may include a first metal layer 320 and a second metal layer 322. However, it is within the ambit of the present disclosure that the Schottky layer 318 may include a single metal layer, as described in connection with FIG. 2.

In various examples, the volume of semiconductor material 302, pockets of doped material 312, cathode substrate 314, cathode contact 316, Schottky layer 318, silicide layer 324, and anode contact 326 may be substantially identical to the analogous volume of semiconductor material 102, pockets of doped material 112, cathode substrate 114, cathode contact 116, Schottky layer 118, silicide layer 124, and anode contact 126 of FIG. 1 and are not described again here for the sake of brevity.

The silicon layer 330 may be implanted, deposited, or otherwise provided along the first end 304 to form a blanket layer of silicon across the first end 304. The silicon layer 330 may underlie the Schottky layer 318. In various examples, the silicon layer 330 may be implanted prior to formation of the pockets of doped material 312. The silicon layer 330 may extend between each of the pockets of doped material 312. The pockets of doped material 312 may extend closer to the second end 306 than the silicon layer 330. Other alternative dimensions and shapes of the doped material pockets and the silicon layer are within the ambit of certain aspects of the example SBD. The channels 328 may extend through the volume of semiconductor material 302 between the respective silicon layer 330 and the cathode substrate 314.

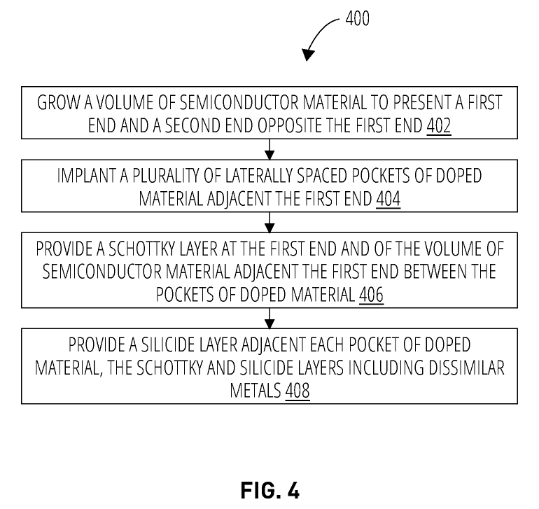

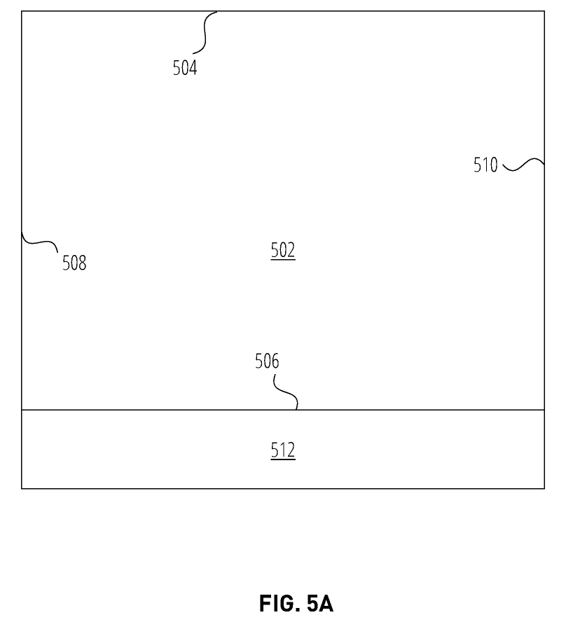

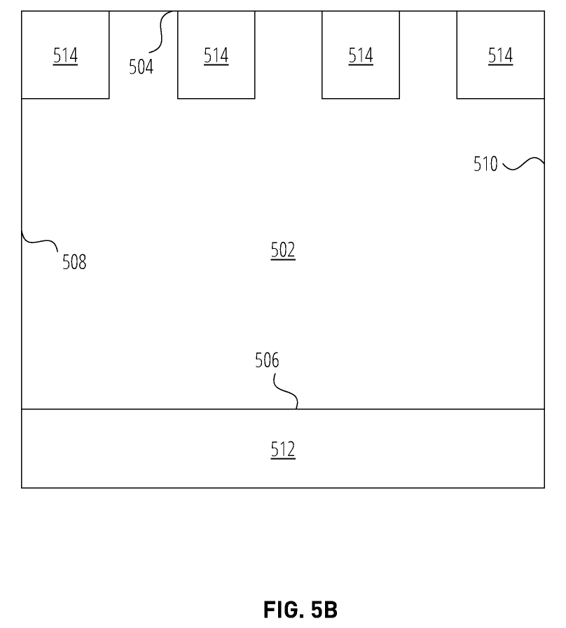

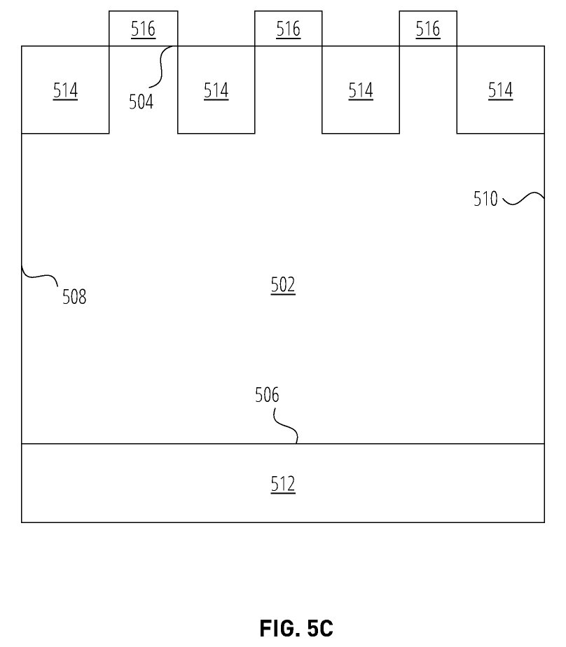

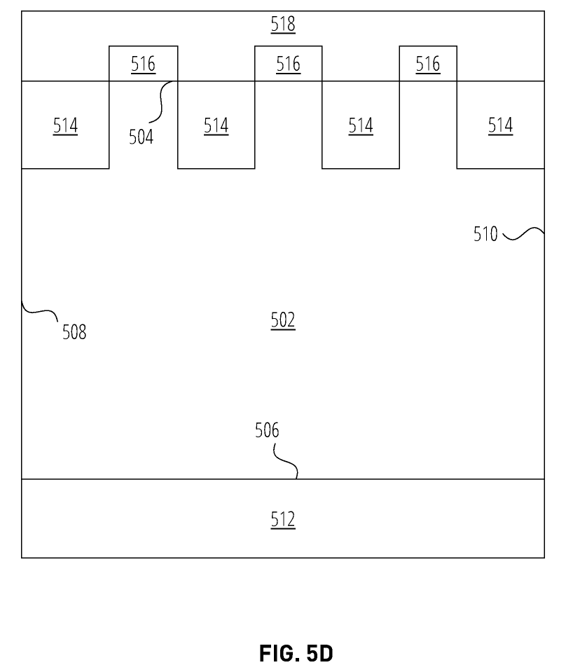

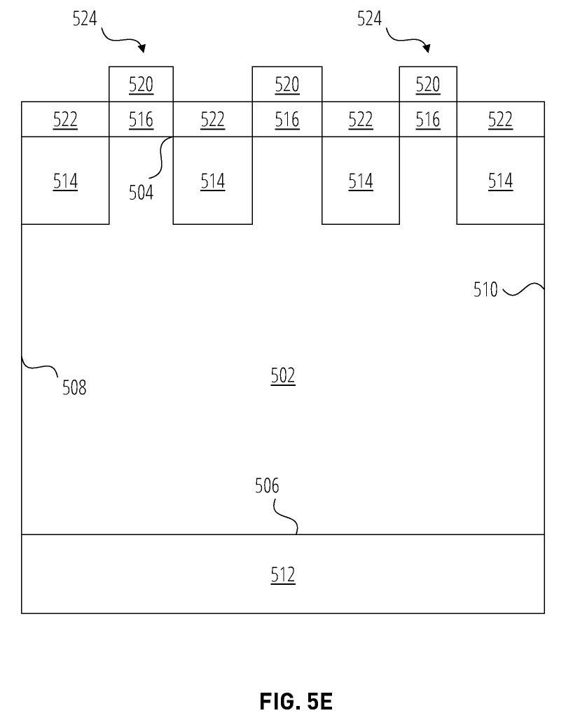

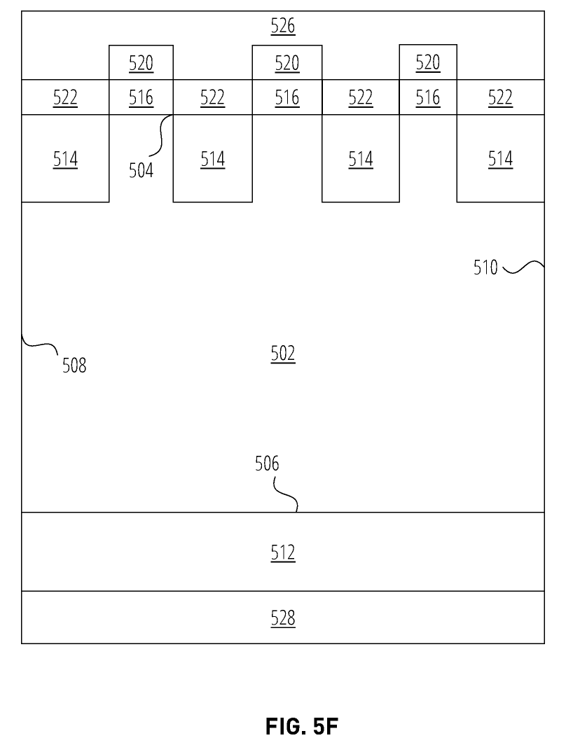

Referring to FIG. 4, an example method 400 of manufacturing an SBD, such as the SBD 100, the SBD 200, or the SBD 300 described above, may include the operations set forth below. Referring additionally to FIGS. 5A-5F, example results of various operations are shown.

Referring to operation 402, the method 400 begins by epitaxially growing a volume of semiconductor material 502 to present a first end 504 and a second end 506 opposite the first end 504, a first side 508 and a second side 510, on a cathode substrate 512, as shown in FIG. 5A. The cathode substrate 512 may be constructed from or otherwise include an N+ substrate material. The volume of semiconductor material 502 may be an N-type semiconductor material. In various examples, the volume of semiconductor material 502 may include silicon carbide (SiC), although it is within the ambit of the present disclosure that the volume of semiconductor material 502 may include silicon.

Referring to operation 404, a plurality of laterally spaced pockets of doped material 514 may be implanted (e.g., via ion implantation), deposited, or otherwise provided adjacent the first end 504, as shown in FIG. 5B. The doped material pockets pockets of doped material 514 may extend from the first end 504 toward the second end 506. The pockets of doped material 514 may be constructed from or otherwise include a P+ material. According to certain examples, the doped material pockets may alternatively be formed of a single unitary implant which may or may not be subsequently modified (e.g., by etching or other suitable techniques).

Referring to operation 406, a Schottky layer 524 may be provided adjacent the first end 504 of the volume of semiconductor material 502 between the pockets of doped material 514, as shown in FIGS. 5C and 5D. Providing the Schottky layer 524 may include forming a first metal layer 516 adjacent the first end 504 between the pockets of doped material 514 and forming (e.g., depositing) a uniform blanket metal layer 518 over the first end 504 and the first metal layer 516. The blanket metal layer 518 may comprise titanium or another conductive metal, such as nickel or cobalt. The blanket metal layer 518 may be formed as a continuous layer extending between the first side 508 and the second side 510.

The first metal layer 516 may be formed by placing a mask across the first end 504. The mask may cover the pockets of doped material 514 and define gaps between the pockets of doped material 514. The first metal layer 516 may be formed between the gaps. However, alternative techniques may be utilized to form the first metal layer 516, such as depositing a uniform layer of tungsten across the first end 504 and etching portions of the tungsten covering the pockets of doped material 514. The first metal layer 516 may comprise tungsten.

Referring to operation 408, a silicide layer 522 may be provided adjacent each pocket of doped material 514, as shown in FIG. 5E. The Schottky layer 524 and the silicide layer 522 may include dissimilar metals, as described above. The silicide layer 522 may be formed by interactions of the blanket metal layer 518 with silicon particles of the volume of semiconductor material 502. For example, the interactions may be facilitated through an annealing process or an ion beam mixing process, although other silicide formation processes may be utilized within the scope of the present disclosure. The silicide layer 522 may form an Ohmic contact with the volume of semiconductor material 502, as described above.

Portions of the blanket metal layer 518 overlying the first metal layer 516 may form a second metal layer 520, as shown in FIG. 5E. The second metal layer 520 and the first metal layer 516 may cooperatively form the Schottky layer 524. However, the first metal layer 516 alone may form the Schottky layer 524 (e.g., as described in connection with FIG. 2), where the second metal layer 520 may be removed (e.g., by etching).

In various examples, the method 400 may further include providing a silicon layer (e.g., the silicon layer 330 of FIG. 3) adjacent the first end 504 of the volume of semiconductor material 502. The silicon layer may underlie the Schottky layer 524. It is within the scope of the present disclosure for the silicon layer to be formed within the volume of semiconductor material 502 by implantation, although provision of the silicon layer may be by other means, such as deposition, epitaxial growth, etc., according to some aspects of the various examples. The silicon layer may extend from the first end 504 toward the second end 506, with a length of the extension defining a thickness of the silicon layer. In various examples, the thickness of the silicon layer may be about fifteen (15) to about one hundred (100) nanometers, although alternative silicon layer thicknesses are within the ambit of certain examples. The silicon layer may extend between the pockets of doped material 514. The pockets of doped material 514 may extend toward the second end 506 beyond the silicon layer.

It will be appreciated by one of ordinary skill in the art that the silicon layer may be implanted either before or after the pockets of doped material 514, without departing from the scope of the present disclosure.

The method 400 may further include placing a cathode contact 528 adjacent the cathode substrate 512, as shown in FIG. 5F. The cathode contact 528 may be formed of a conductive metal, such as aluminum, nickel, copper, and combinations thereof. The cathode contact 528 may contact the cathode substrate 512 and may be spaced apart from the second end 506. The cathode contact 528 may span the cathode substrate 512.

The method 400 may further include placing an anode contact 526 on the Schottky layer 524, as shown in FIG. 5F. The anode contact 526 may contact the Schottky layer 524. More particularly, the anode contact 526 may contact the second metal layer 520, such that the second metal layer 520 is interposed between the anode contact 526 and the first metal layer 516. As noted above, the first metal layer 516, second metal layer 520, and anode contact 526 may be formed of dissimilar metals.

Additional processing may be performed as desired.

### FEATURE COMBINATIONS

In accordance with various examples of the present disclosure, a Schottky barrier diode (SBD) may include a volume of semiconductor material presenting opposite first and second ends, a plurality of laterally spaced pockets of doped material extending into the volume of semiconductor material adjacent the first end, a Schottky layer located adjacent the first end between the pockets of doped material, and a silicide layer located adjacent each pocket of doped material. The Schottky and silicide layers include dissimilar metals.

In accordance with various examples of the present disclosure, a method of making an SBD may include: growing a volume of semiconductor material to present a first end and a second end opposite the first end; implanting a plurality of laterally spaced pockets of doped material adjacent the first end; providing a Schottky layer at the first end and of the volume of semiconductor material adjacent the first end between the pockets of doped material; and providing a silicide layer adjacent each pocket of doped material. The Schottky and silicide layers include dissimilar metals.

The preceding examples may include any one or more of the following features.

The Schottky layer may comprise tungsten.

The SBD may include a silicon layer located adjacent the first end between the pockets of doped material so as to underlie the Schottky layer.

The pockets of doped material may extend toward the second end beyond the silicon layer.

The silicide layer may comprise titanium silicide.

The SBD may include a layer of titanium overlying the Schottky layer.

The SBD may include may comprise an anode contact adjacent the silicide layer and the Schottky layer.

The Schottky layer may include a first metal layer contacting the volume of semiconductor material and a second metal layer contacting the anode contact.

The first metal layer may comprise tungsten.

The second metal layer may comprise titanium.

The silicide layer may comprise titanium silicide.

The SBD may include a cathode substrate located at the second end.

The volume of semiconductor material may include an N-type epitaxial material, the pockets of doped material may include a P+ material, and the cathode substrate may comprise an N+ material.

The Schottky layer may include a first metal layer contacting the volume of semiconductor material and a second metal layer overlying the first metal layer, the first metal layer may comprise tungsten, the second metal layer may comprise titanium.

The method may include implanting a silicon layer adjacent the first end between the pockets of doped material so as to underlie the Schottky layer.

The method may include extending the pockets of doped material toward the second end beyond the silicon layer.

The method may include providing an anode contact on the Schottky layer.

The operation of providing the Schottky layer may include providing a first metal layer in contact with the volume of semiconductor material and a second metal layer in contact with the anode contact

The first metal layer may comprise tungsten, the second metal layer may comprise titanium.

The silicide layer may comprise titanium silicide. The Schottky layer may comprise tungsten.

The operation of growing the volume of semiconductor material may include growing an N-type epitaxial material on an N+ cathode substrate, with the cathode substrate being located at the second end.

The method may include providing a cathode contact adjacent the cathode substrate.

The operation of implanting the pockets of doped material may include forming the pockets of doped material of a P+ material.

### GENERAL CONSIDERATIONS

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

For example, although described herein with regard or in relation to one or more particular kinds of electronic devices (e.g., Schottky barrier diodes), the technology may be more broadly applicable to one or more other kinds of electronic devices as well. Additionally, the various example materials identified herein may, in some aspects, be replaced or supplemented with substantially any other suitable material. For example, the semiconductor material may include silicon carbide, gallium nitride, zinc oxide, or other suitable material.

It will be appreciated that the sides of the illustrated volume of semiconductor material are defined herein merely as an example, and may in various examples represent only a portion of semiconductor material relative to the illustrated device. In practice, the volume of semiconductor material may extend laterally (leftward and rightward when viewing FIG. 1) beyond the bounds illustrated in the drawings to present additional semiconductor material in which additional devices may be provided. (The semiconductor material may similarly extend inwardly or outwardly (relative to the lateral or cross-sectional direction depicted in FIG. 1) to present additional devices in a direction transverse to the lateral direction.) Such additional devices may be similarly or alternatively constructed to the illustrated SBD 100 or may be entirely different devices providing different operations or functions than the illustrated device 100. In other words, in practice, the illustrated device 100 may be just one of numerous devices spaced laterally and transversely within a single, integrally formed component, such as a wafer or integrated circuit (not shown).

Additionally, in general, unless otherwise specified or unless one with ordinary skill in the art would understand otherwise, doping concentrations (measured in parts per cubic centimeter) for contact implants may be approximately between 10^18 and 10^22; doping concentrations for channel and threshold forming implants may be approximately between 10^16 and 10^17; doping concentrations for shielding implants may be approximately between 10^17 and 10^19; and doping concentrations for conductivity improvement implants may be approximately between 10^16 and 10^17. Relatedly, a structure or region may contain two or more different doping doses.

In this description, references to “one embodiment,” “an embodiment,” “embodiments,” “an example,” “one example,” or “examples” mean that the feature or features being referred to are included in at least one embodiment or example of the technology. Separate references to “one embodiment,” “an embodiment,” “embodiments,” “an example,” “one example,” or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

What is claimed is:

1. A Schottky barrier diode (SBD), comprising:
a volume of semiconductor material presenting opposite first and second ends;
a plurality of laterally spaced pockets of doped material extending into the volume of semiconductor material adjacent the first end;
a Schottky layer located adjacent the first end between the pockets of doped material; and
a silicide layer located adjacent each pocket of doped material, the Schottky and silicide layers including dissimilar metals.

2. The SBD of claim 1,
the Schottky layer comprising tungsten.

3. The SBD of claim 2, comprising:
a silicon layer located adjacent the first end between the pockets of doped material so as to underlie the Schottky layer.

4. The SBD of claim 3,
the pockets of doped material extending toward the second end beyond the silicon layer.

5. The SBD of claim 2,
the silicide layer comprising titanium silicide.

6. The SBD of claim 5,
a layer of titanium overlying the Schottky layer.

7. The SBD of claim 1, comprising:
an anode contact adjacent the silicide layer and the Schottky layer.

8. The SBD of claim 7,
the Schottky layer including a first metal layer contacting the volume of semiconductor material and a second metal layer contacting the anode contact.

9. The SBD of claim 8,
the first metal layer comprising tungsten.

10. The SBD of claim 8
the second metal layer comprising titanium.

11. The SBD of claim 1,
the silicide layer comprising titanium silicide.

12. The SBD of claim 1, comprising:
a cathode substrate located at the second end,
the volume of semiconductor material including an N-type epitaxial material,
the pockets of doped material including a P+ material,
the cathode substrate comprising an N+ material.

13. The SBD of claim 1,
the Schottky layer including a first metal layer contacting the volume of semiconductor material and a second metal layer overlying the first metal layer,
the first metal layer comprising tungsten,
the second metal layer comprising titanium.

14. A method of making a Schottky barrier diode (SBD), comprising:
growing a volume of semiconductor material to present a first end and a second end opposite the first end;
implanting a plurality of laterally spaced pockets of doped material adjacent the first end;
providing a Schottky layer at the first end and of the volume of semiconductor material adjacent the first end between the pockets of doped material; and
providing a silicide layer adjacent each pocket of doped material, the Schottky and silicide layers including dissimilar metals.

15. The method of claim 14, comprising:
implanting a silicon layer adjacent the first end between the pockets of doped material so as to underlie the Schottky layer.

16. The method of claim 15,
extending the pockets of doped material toward the second end beyond the silicon layer.

17. The method of claim 14, comprising:
providing an anode contact on the Schottky layer.

18. The method of claim 17,
the operation of providing the Schottky layer including providing a first metal layer in contact with the volume of semiconductor material and a second metal layer in contact with the anode contact,
the first metal layer comprising tungsten,
the second metal layer comprising titanium.

19. The method of claim 14,
the silicide layer comprising titanium silicide,
the Schottky layer comprising tungsten.

20. The method of claim 14, comprising:
the operation of growing the volume of semiconductor material including growing an N-type epitaxial material on an N+ cathode substrate, with the cathode substrate being located at the second end,
providing a cathode contact adjacent the cathode substrate,
the operation of implanting the pockets of doped material including forming the pockets of doped material of a P+ material.
